(19) United States
(12) Patent Application Publication
(10) Pub. No.: US 2024/0313742 A1
(43) Pub. Date: Sep. 19, 2024

(54) PIEZOELECTRIC VIBRATING PIECE, PIEZOELECTRIC VIBRATOR, AND OSCILLATOR

(71) Applicant: Sll Crystal Technology Inc., Chiba-shi (JP)

(72) Inventors: Masanori KATO, Chiba-shi (JP); Naoya ICHIMURA, Chiba-shi (JP)

(21) Appl. No.: 18/600,043

(22) Filed: Mar. 8, 2024

(30) Foreign Application Priority Data
Mar. 14, 2023 (JP) 2023-039308

(51) Int. Cl. H03H 9/21; H10N 30/02; H10N 30/071; H10N 30/20

(52) U.S. Cl. CPC H03H 9/21; H10N 30/02; H10N 30/071; H10N 30/20

(57) ABSTRACT

A decrease in vibration efficiency due to size reduction of a tuning-fork type piezoelectric vibrating piece is prevented. A piezoelectric vibrating piece includes a base portion, and a pair of vibrating arm portions extending in parallel from the base portion. Each of the vibrating arm portions includes an arm portion extending from the base portion, and a head portion connected to a distal end of the arm portion and having a width larger than that of the arm portion. The piezoelectric vibrating piece satisfies the following relation: 0.13×10¹²≤Vh(Lh²+Wh²)≤0.39×10¹², where Lh [μm] is a length of the head portion, Wh [μm] is a width of the head portion, and Vh [μm³] is a volume of the head portion.

### RELATED APPLICATIONS

This application claims priority to Japanese Patent application No. JP2023-039308 filed on Mar. 14, 2023, the entire content of which is incorporated herein by reference.

### BACKGROUND OF THE INVENTION

### 1. Field of the Invention

The present disclosure relates to a piezoelectric vibrating piece, a piezoelectric vibrator, and an oscillator.

### 2. Description of the Related Art

In the related art, a tuning-fork type piezoelectric vibrating piece is known. This piezoelectric vibrating piece includes a base portion and a pair of vibrating arm portions extending in parallel from the base portion. In order to reduce a size of the piezoelectric vibrating piece and improve a vibration property, a weight portion (head portion) called a hammerhead may be formed at a distal end of each vibrating arm portion (for example, see PTL 1 and PTL 2 to be described later).

### 3. Citations

### Patent Literature

PTL 1: JP6521148B
PTL 2: JP7060073B

### SUMMARY OF THE INVENTION

When the size of the above-mentioned tuning-fork type piezoelectric vibrating piece is made smaller than before, a ratio of a total length with respect to a total width of the piezoelectric vibrating piece becomes smaller, and as a result, it is necessary to relatively increase a size of the head portion at the distal end for frequency adjustment. In this case, there is a problem that the head portion reduces vibration efficiency of the vibrating arm portion, and a crystal impedance (CI) value is increased.

The present disclosure is made in view of the above-mentioned circumstances, and an object thereof is to prevent a decrease in the vibration efficiency due to the size reduction of the tuning-fork type piezoelectric vibrating piece.

(1) A piezoelectric vibrating piece according to one aspect of the present disclosure including a base portion; and a pair of vibrating arm portions extending in parallel from the base portion, in which each of the vibrating arm portions includes: an arm portion extending from the base portion; and a head portion connected to a distal end of the arm portion and having a width larger than that of the arm portion, and the piezoelectric vibrating piece satisfies the following relation: 0.13×10¹²≤ Vh(Lh²+Wh²)≤0.39×10¹², where Lh [μm] is a length of the head portion, Wh [μm] is a width of the head portion, and Vh [μm³] is a volume of the head portion.

According to the piezoelectric vibrating piece according to this aspect, by numerically limiting a dimension-based portion of an inertia moment during vibration of the head portion, it is possible to prevent a change in frequency while reducing a CI value.

(2) The piezoelectric vibrating piece according to aspect (1), in which the following relation may be satisfied, Vh(Lh²+Wh²)≤0.33×10¹².

In this case, the CI value can be reduced by about 5% compared to that when Vh(Lh²+Wh²)=0.39×10¹².

(3) The piezoelectric vibrating piece according to aspect (1) or (2), in which the following relation may be satisfied, 0.145×10¹²≤Vh(Lh²+Wh²).

In this case, the change in frequency can be reduced to within 5% from that when Vh(Lh²+Wh²)=0.13×10¹².

(4) The piezoelectric vibrating piece according to any one of aspects (1) to (3), in which the following relation may be satisfied, 0.24≤ Lh/La≤0.35, where La [μm] is a length of the vibrating arm portion from the base portion to the distal end.

In this case, by numerically limiting a ratio of a length of the head portion to a length of the vibrating arm portion, it is possible to reduce the change in frequency while reducing the CI value.

(5) The piezoelectric vibrating piece according to aspect (4), in which the following relation may be satisfied, Lh/La≤0.32.

In this case, the CI value can be reduced by about 5% compared to that when Lh/La=0.35.

(6) The piezoelectric vibrating piece according to aspect (4) or (5), in which the following relation may be satisfied, 0.27≤ Lh/La.

In this case, the change in frequency can be reduced to within 5% from that when Lh/La=0.24.

(7) The piezoelectric vibrating piece according to any one of aspects (1) to (6), in which the piezoelectric vibrating piece may further include a pair of side arms extending from the base portion and disposed on both sides of the pair of vibrating arm portions in a width direction.

In this case, it is possible to prevent a decrease in vibration efficiency due to size reduction of the piezoelectric vibrating piece including the pair of side arms.

(8) The piezoelectric vibrating piece according to any one of aspects (1) to (6), in which the piezoelectric vibrating piece may further include a center arm extending from the base portion and disposed between the pair of vibrating arm portions.

In this case, it is possible to prevent a decrease in vibration efficiency due to size reduction of the piezoelectric vibrating piece including the center arm.

(9) A piezoelectric vibrator according to one aspect of the present disclosure including the piezoelectric vibrating piece according to any one of aspects (1) to (8), and a package in which the piezoelectric vibrating piece is sealed.

According to the piezoelectric vibrator according to this aspect, a small and high-quality piezoelectric vibrator can be obtained.

(10) An oscillator according to one aspect of the present disclosure including the piezoelectric vibrator according to aspect 9, and an integrated circuit electrically connected to the piezoelectric vibrator.

According to the oscillator according to this aspect, a small and high-quality oscillator can be obtained.

According to one aspect of the present disclosure described above, it is possible to prevent a decrease in vibration efficiency due to size reduction of the tuning-fork type piezoelectric vibrating piece.

### BRIEF DESCRIPTION OF THE DRAWINGS

FIG. 1 is an exploded perspective view of a piezoelectric vibrator according to a first embodiment.

FIG. 2 is a plan view illustrating dimensional relations of a piezoelectric vibrating piece according to the first embodiment.

FIG. 3 is a graph showing an analysis result of a relation between Vh×(Lh²+Wh²) and R1 (CI value) of the piezoelectric vibrating piece according to the first embodiment.

FIG. 4 is a graph showing an analysis result of a relation between Vh×(Lh²+Wh²) and F (frequency) of the piezoelectric vibrating piece according to the first embodiment.

FIG. 5 is a graph showing an analysis result of a relation between Lh/La and R1 (CI value) of the piezoelectric vibrating piece according to the first embodiment.

FIG. 6 is a graph showing an analysis result of a relation between Lh/La and F (frequency) of the piezoelectric vibrating piece according to the first embodiment.

FIG. 7 is a plan view of a piezoelectric vibrating piece according to a second embodiment.

### DETAILED DESCRIPTION OF THE PREFERRED EMBODIMENTS

### First Embodiment

First, a first embodiment according to the present disclosure will be described with reference to the drawings.

### Oscillator

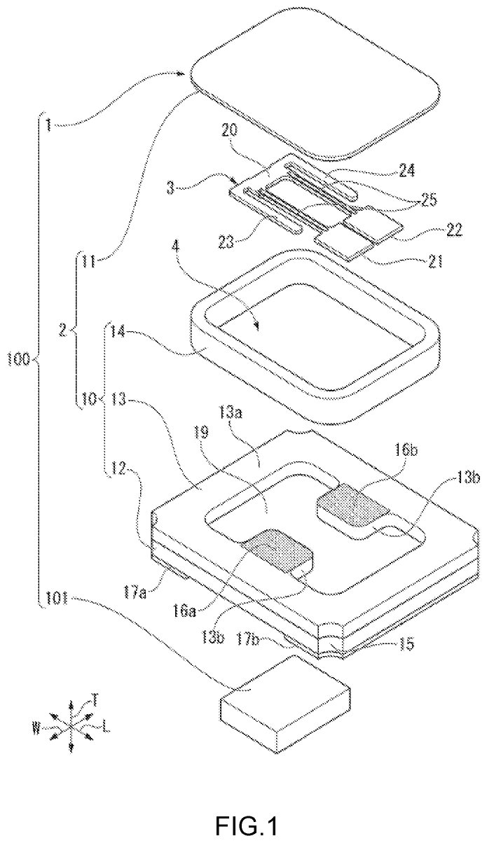

FIG. 1 is an exploded perspective view of an oscillator 100 according to the first embodiment.

The oscillator 100 shown in FIG. 1 includes a piezoelectric vibrator 1 that functions as an oscillation element, and an integrated circuit 101 for an oscillator. The integrated circuit 101 is electrically connected to the piezoelectric vibrator 1 via, for example, a substrate (not shown).

When power is supplied to the piezoelectric vibrator 1, a piezoelectric vibrating piece 3 of the piezoelectric vibrator 1 vibrates. The vibration of the piezoelectric vibrating piece 3 is converted into an electrical signal due to a piezoelectric property of the piezoelectric vibrating piece 3. This electrical signal is output from the piezoelectric vibrator 1 to the integrated circuit 101. The integrated circuit 101 generates a frequency signal by performing various processing on the electrical signal output from the piezoelectric vibrator 1.

The oscillator 100 can be applied to, for example, a single-function oscillator for a timepiece, a timing control device that controls operation timings of various devices such as a computer, and a device that provides time or a calendar. The integrated circuit 101 is configured according to functions required for the oscillator 100, and may include a so-called real-time clock (RTC) module.

### Piezoelectric Vibrator

As shown in FIG. 1, the piezoelectric vibrator 1 is a ceramic package type surface-mounted vibrator including a package 2 provided with a hermetically sealed cavity 4 therein, and the tuning-fork type piezoelectric vibrating piece 3 accommodated in the cavity 4.

The piezoelectric vibrator 1 is formed into a generally rectangular parallelepiped shape, and in the embodiment, in a plan view of the piezoelectric vibrator 1, a longitudinal direction is referred to as a length direction L, and a lateral direction is referred to as a width direction W, and a direction perpendicular to the length direction L and the width direction W is referred to as a thickness direction T.

The package 2 includes a package body 10 and a sealing plate 11 that is bonded to the package body 10 and forms the cavity 4 with the package body 10 therebetween.

The package body 10 includes a first base substrate 12 and a second base substrate 13 that are bonded to each other in an overlapping state, and a seal ring 14 that is bonded to the second base substrate 13.

The first base substrate 12 is a ceramic substrate formed into a substantially rectangular shape in a plan view. The second base substrate 13 is a ceramic substrate formed into a substantially rectangular shape in a plan view, which has the same external shape as the first base substrate 12, and is integrally bonded to the first base substrate 12 by a method such as sintering while stacked on the first base substrate 12.

At four corners of the first base substrate 12 and the second base substrate 13, cutout portions 15 each having a quarter-arc shape in a plan view are formed throughout the thickness direction T. The first base substrate 12 and the second base substrate 13 are manufactured by, for example, stacking and bonding two wafer-shaped ceramic substrates, forming a plurality of through-holes penetrating both the ceramic substrates in a matrix shape, and then cutting both the ceramic substrates into a grid shape using each through-hole as a reference. At this time, the through-hole is divided into four parts, thereby forming the cutout portion 15.

Further, an upper surface of the second base substrate 13 is a mounting surface 13a on which the piezoelectric vibrating piece 3 is mounted.

The first base substrate 12 and the second base substrate 13 are made of ceramic, but specific examples of a ceramic material include, for example, high temperature co-fired ceramic (HTCC) made of alumina, and low temperature co-fired ceramic (LTCC) made of glass ceramic.

The seal ring 14 is a conductive frame-shaped member having an outer dimension slightly smaller than those of the first base substrate 12 and the second base substrate 13, and is bonded to the mounting surface 13a of the second base substrate 13. Specifically, the seal ring 14 is bonded onto the mounting surface 13a by baking using a brazing material such as a silver braze, a solder material, or the like, or is bonded by welding or the like to a metal bonding layer formed (for example, by electrolytic plating, electroless plating, vapor deposition, or sputtering) on the mounting surface 13a.

Examples of a material of the seal ring 14 include, for example, a nickel-based alloy, and specifically, may be selected from Kovar, Elinvar, Invar, 42-alloy, and the like. In particular, as the material of the seal ring 14, it is preferable to select a material having a thermal expansion coefficient close to those of the first base substrate 12 and the second base substrate 13, which are made of ceramic. For example, when the first base substrate 12 and the second base substrate 13 are made of alumina having a thermal expansion coefficient of 6.8×10⁻⁶/° C., it is preferable that the seal ring 14 is made of Kovar having a thermal expansion coefficient of 5.2×10⁻⁶/° C. or 42-alloy having a thermal expansion coefficient of 4.5×10⁻⁶/° C. to 6.5×10⁻⁶/° C.

The sealing plate 11 is a conductive substrate stacked on the seal ring 14, and is hermetically bonded to the package body 10 by bonding to the seal ring 14. A space defined by the sealing plate 11, the seal ring 14, and the mounting surface 13a of the second base substrate 13 functions as the cavity 4 that is hermetically sealed.

Examples of a welding method for the sealing plate 11 include seam welding by bringing roller electrodes into contact, laser welding, ultrasonic welding, and the like. Furthermore, in order to ensure the welding between the sealing plate 11 and the seal ring 14, it is preferable to form bonding layers of nickel, gold, or the like, which are compatible with each other, on at least a lower surface of the sealing plate 11 and an upper surface of the seal ring 14, respectively.

A pair of electrode pads 16a and 16b, which are connection electrodes to the piezoelectric vibrating piece 3, are formed on the mounting surface 13a of the second base substrate 13 with an interval in the width direction W. A pair of external electrodes 17a and 17b are formed on a lower surface of the first base substrate 12 with an interval in the length direction L. These electrode pads 16a and 16b and external electrodes 17a and 17b are, for example, a single-layer film of a single metal formed by vapor deposition or sputtering, or a laminated film obtained by laminating different metals, and are electrically connected to each other.

That is, conduction electrodes (not shown) that allow one electrode pad 16a and one external electrode 17a to electrically conduct each other are formed on the first base substrate 12 and the second base substrate 13. In addition, conduction electrodes (not shown) that allow the other electrode pad 16b and the other external electrode 17b to electrically conduct each other are formed on the first base substrate 12 and the second base substrate 13. These conduction electrodes extend in the thickness direction T in the first base substrate 12 and the second base substrate 13, and extend in a planar direction (a direction including the length direction L and the width direction W) between the first base substrate 12 and the second base substrate 13.

A recess 19, which avoids contact of a pair of vibrating arm portions 21 and 22, and the like with the piezoelectric vibrating piece 3 when the pair of vibrating arm portions 21 and 22, and the like are displaced (flexurally deformed) in the thickness direction T due to influence of impact of a fall or the like, is formed on a portion facing the piezoelectric vibrating piece 3 on the mounting surface 13a of the second base substrate 13. The recess 19 is a through hole penetrating the second base substrate 13, and is formed in a square shape in a plan view inside the seal ring 14 with rounded four corners. The pair of electrode pads 16a and 16b are formed on a pair of protrusions 13b that protrude inward in the width direction W from both sides of the recess 19 in the width direction W.

The piezoelectric vibrating piece 3 is mounted such that a pair of mount electrodes of a pair of side arms 23 and 24 extending from a base portion 20 are brought into contact with the pair of electrode pads 16a and 16b via a metal bump, a conductive adhesive, or the like (not shown). Accordingly, the piezoelectric vibrating piece 3 is supported in a floating state above the mounting surface 13a of the second base substrate 13, and becomes a state of electrically connected to the pair of electrode pads 16a and 16b, respectively.

### Piezoelectric Vibrating Piece

The piezoelectric vibrating piece 3 is a tuning-fork type vibrating piece made of a piezoelectric material such as crystal, lithium tantalate, or lithium niobate, and vibrates when a predetermined voltage is applied.

The piezoelectric vibrating piece 3 includes the base portion 20 and the pair of vibrating arm portions 21 and 22.

The pair of vibrating arm portions 21 and 22 extend parallel to each other along the length direction L from the base portion 20. A distal end side of each of the pair of vibrating arm portions 21 and 22 in an extending direction is a free end that vibrates with a proximal end side (base portion 20 side) being a fixed end. Each of the pair of vibrating arm portions 21 and 22 is of a hammerhead type in which a width dimension at the distal end side is larger than that at the proximal end side.

When the pair of vibrating arm portions 21 and 22 are of a hammerhead type, weights at respective distal end sides of the vibrating arm portions 21 and 22 and inertia moments thereof during vibration can be increased, and as a result, the vibrating arm portions 21 and 22 can be made easier to vibrate. Therefore, lengths of the vibrating arm portions 21 and 22 can be shortened, and there is an advantage that size reduction can be achieved.

The pair of vibrating arm portions 21 and 22 are respectively provided with grooves 25 formed on both surfaces in the thickness direction T along the length direction L (extending direction) of the pair of vibrating arm portions 21 and 22. The grooves 25 are formed, for example, between the proximal end sides and the distal end sides of the pair of vibrating arm portions 21 and 22, respectively.

Further, the pair of vibrating arm portions 21 and 22 are provided with two systems of excitation electrodes that are insulated from each other and cause the vibrating arm portions 21 and 22 to vibrate in the width direction W.

The base portion 20 integrally connects the proximal ends of the pair of vibrating arm portions 21 and 22. Furthermore, the pair of side arms 23 and 24 extend from the base portion 20. The pair of side arms 23 and 24 each have an L shape in a plan view, and surround the pair of vibrating arm portions 21 and 22 from the outside in the width direction W. Specifically, the pair of side arms 23 and 24 are provided in a protruding manner outward in the width direction W, and then extend along the length direction L in parallel to the pair of vibrating arm portions 21 and 22.

When operating the piezoelectric vibrator 1 configured in this manner, a predetermined driving voltage is applied to the pair of external electrodes 17a and 17b. Accordingly, current can be passed through the excitation electrodes of the pair of vibrating arm portions 21 and 22 of the piezoelectric vibrating piece 3 via the pair of electrode pads 16a and 16b. Due to interaction of the excitation electrodes, the pair of vibrating arm portions 21 and 22 vibrate at a predetermined resonance frequency in a direction in which the pair of vibrating arm portions 21 and 22 approach and separate from each other (width direction W). The vibration of the pair of vibrating arm portions 21 and 22 can be used as a time source, a timing source for control signals, a reference signal source, and the like.

In the embodiment, a ceramic package type surface-mounted vibrator was described as the piezoelectric vibrator 1 using the piezoelectric vibrating piece 3, but it is also possible to apply the piezoelectric vibrating piece 3 to a glass package type piezoelectric vibrator 1 in which a base substrate and a lid substrate formed of a glass material are bonded by anodic bonding.

Furthermore, in the embodiment, the piezoelectric vibrating piece 3 in which the grooves 25 are formed in the pair of vibrating arm portions 21 and 22 is used, but a piezoelectric vibrating piece in which the grooves 25 are not formed may also be used.

### Dimension of Piezoelectric Vibrating Piece

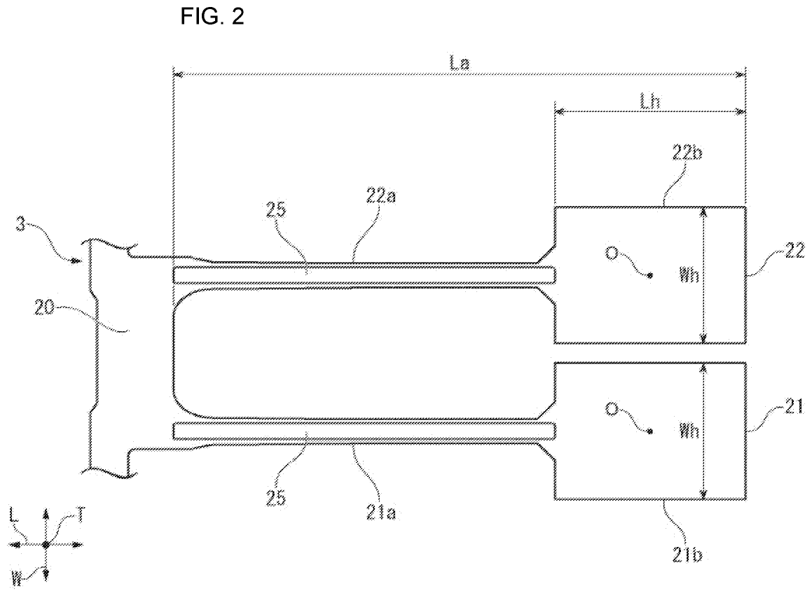

FIG. 2 is a plan view illustrating dimensional relations of the piezoelectric vibrating piece 3 according to the first embodiment.

As shown in FIG. 2, the pair of vibrating arm portions 21 and 22 of the piezoelectric vibrating piece 3 include arm portions 21a and 22a extending in the length direction L from the base portion 20, and head portions 21b and 22b connected to distal ends of the arm portions 21a and 22a.

The excitation electrodes (not shown) are formed on outer surfaces of the arm portions 21a and 22a. The excitation electrodes cause the pair of vibrating arm portions 21 and 22 to vibrate in the width direction W when a predetermined driving voltage is applied. The excitation electrodes are patterned on the outer surfaces of the arm portions 21a and 22a in a state where the excitation electrodes are electrically insulated from each other.

Weight metal films (not shown) are formed on the outer surfaces of the head portions 21b and 22b. The weight metal films are provided to increase masses of the pair of vibrating arm portions 21 and 22 at distal ends thereof and to prevent an increase in resonance frequency when the pair of vibrating arm portions 21 and 22 are shortened. In the embodiment, the weight metal film is formed integrally with the excitation electrode.

The head portions 21b and 22b are formed wider than the arm portions 21a and 22a. Each of the head portions 21b and 22b is formed into a rectangular shape in a plan view. Tapered portions are formed in connection portions of the head portions 21b and 22b and the arm portions 21a and 22a to alleviate stress concentration at the corners. Thicknesses of the head portions 21b and 22b are equal to those of the arm portions 21a and 22a except for the excitation electrodes and the weight metal films.

This piezoelectric vibrating piece 3 satisfies a relation represented by the following Expression (1). In Expression (1), Lh [μm] is a length of each of the head portions 21b and 22b, Wh [μm] is a width of each of the head portions 21b and 22b, and Vh [μm³] is a volume of each of the head portions 21b and 22b. Each of the vibrating arm portions 21 and 22 satisfies a dimensional relation represented by the following Expression (1). The same applies to Expression (2) to be described later.

$$0.13 \times {10}^{12} \leq Vh ( {Lh}^{2} + {Wh}^{2} ) \leq 0.39 \times {10}^{12} \qquad ( 1 )$$

“Lh” refers to a dimension of the head portions 21b and 22b in the length direction L, except for the tapered portions described above. In addition, “Vh(Lh²+Wh²)” refers to a function resulting from inertia moments during vibration of the head portions 21b and 22b. As shown in FIG. 2, when rotation centers O extending in a direction perpendicular to the paper (thickness direction T) is set at centers (centers of gravity) of the head portions 21b and 22b, inertia moments I of rectangular parallelepipeds (head portions 21b and 22b) can be determined by I=ρ×Vh×(Lh²+Wh²)/12. Here, “ρ” is a density of the piezoelectric vibrating piece 3, and when the piezoelectric vibrating piece 3 is made of crystal, ρ=2.65 [g/cm³]. In other words, those other than “Lh”, “Wh”, and “Vh” are constants.

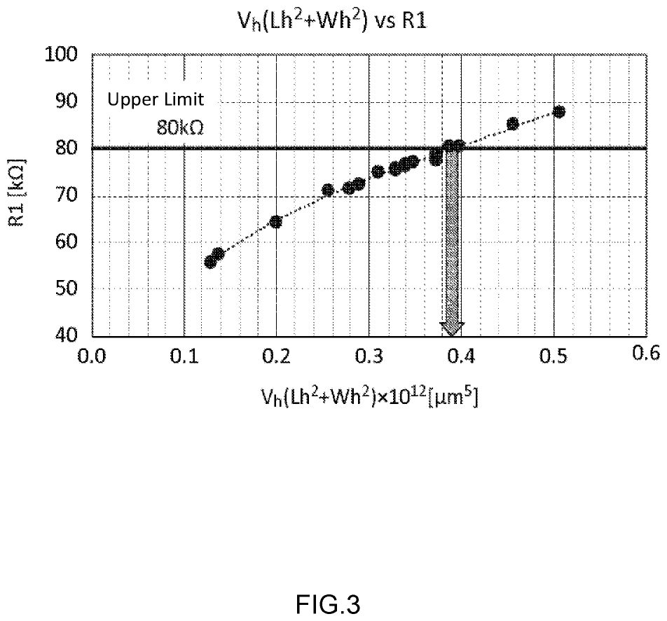

FIG. 3 is a graph showing an analysis result of a relation between Vh×(Lh²+Wh²) and R1 (CI value) of the piezoelectric vibrating piece 3 according to the first embodiment.

As shown in FIG. 3, when Vh(Lh²+Wh²) is 0.39×10¹² [μm⁵] or less, R1 can be reduced to 80 [kΩ] or less. A threshold value of 80 [kΩ] is a value based on specifications of a general tuning-fork type crystal oscillator.

In addition, as shown in FIG. 3, when Vh(Lh²+Wh²) is 0.33×10¹² [μm⁵] or less, R1 can be further reduced by about 5%. Therefore, Vh(Lh²+Wh²) is preferably 0.39×10¹² [μm⁵] or less, and more preferably 0.33×10¹² [μm⁵] or less.

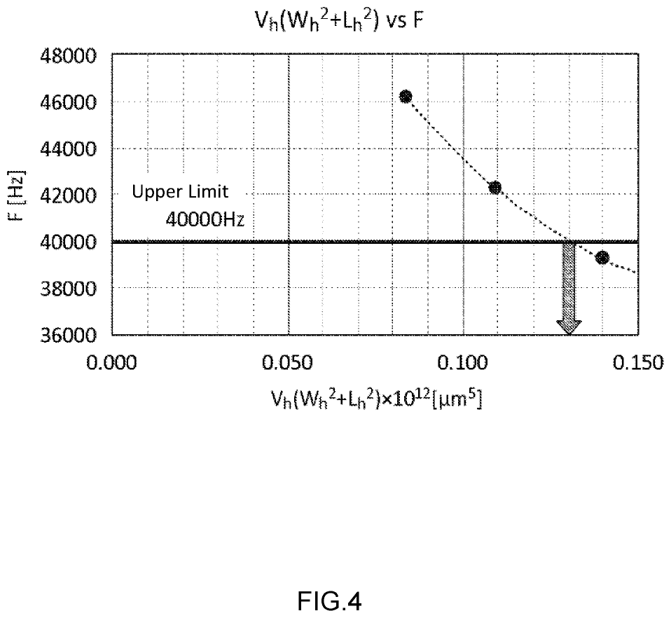

FIG. 4 is a graph showing an analysis result of a relation between Vh×(Lh²+Wh²) and F (frequency) of the piezoelectric vibrating piece 3 according to the first embodiment.

As shown in FIG. 4, when Vh(Lh²+Wh²) is 0.13×10¹² [μm⁵] or more, F can be reduced to 40000 [Hz] or less. A threshold value of 40000 [Hz] is a value based on specifications of a general tuning-fork type crystal oscillator. When F exceeds 40,000 [Hz], in order to prevent the vibration of the piezoelectric vibrating piece 3, it is necessary to form a thick weight metal film (for example, gold) on the head portions 21b and 22b, which increases manufacturing cost of the piezoelectric vibrating piece 3.

In addition, as shown in FIG. 4, when Vh(Lh²+Wh²) is 0.145×10¹² [μm⁵] or more, F can be further reduced by about 5%. Therefore, Vh(Lh²+Wh²) is preferably 0.13×10¹² [μm⁵] or more, and more preferably 0.145×10¹² [μm⁵] or more.

Returning to FIG. 2, the piezoelectric vibrating piece 3 further satisfies a relation represented by the following Expression (2). In Expression (2), Lh [μm] is a length of each of the head portions 21b and 22b, and La [μm] is a length of each of the vibrating arm portions 21 and 22 from the base portion 20 to respective distal ends.

$$0.24 \leq Lh / La \leq 0.35 \qquad ( 2 )$$

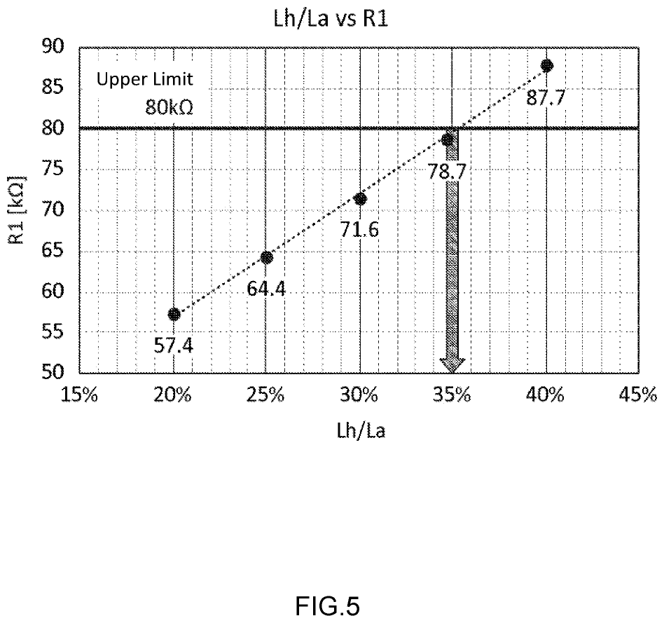

FIG. 5 is a graph showing an analysis result of a relation between Lh/La and R1 (CI value) of the piezoelectric vibrating piece 3 according to the first embodiment. In FIG. 5, La is fixed and Lh is varied.

As shown in FIG. 5, when Lh/La is 0.35 [%] or less, R1 can be reduced to 80 [kΩ] or less. In addition, when Lh/La is 0.32 [%] or less, R1 can be further reduced by about 5%. Therefore, Lh/La is preferably 0.35 [%] or less, and more preferably 0.32 [%] or less.

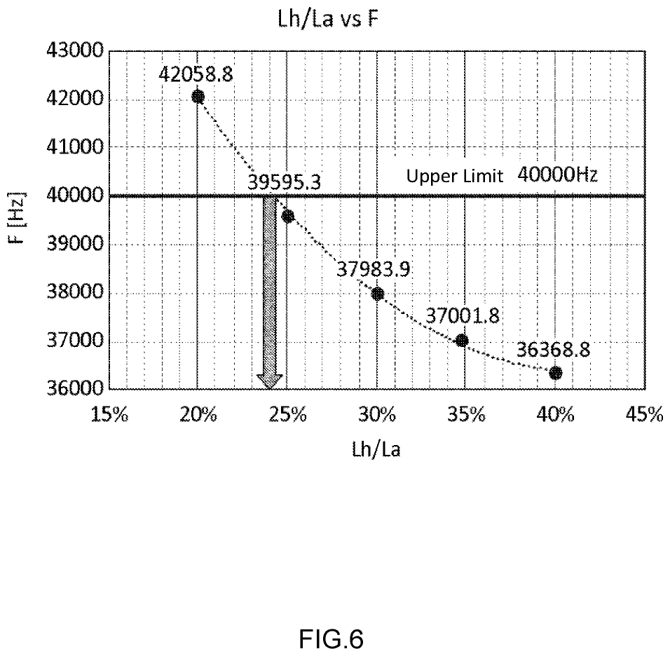

FIG. 6 is a graph showing an analysis result of a relation between Lh/La and F (frequency) of the piezoelectric vibrating piece 3 according to the first embodiment. In FIG. 6, La is fixed and Lh is varied.

As shown in FIG. 6, when Lh/La is 0.24 [%] or more, F can be reduced to 40000 [Hz] or less. In addition, when Lh/La is 0.27 [%] or more, F can be further reduced by about 5%. Therefore, Lh/La is preferably 0.24 [%] or more, and more preferably 0.27 [%] or more.

As described above, according to the piezoelectric vibrating piece 3 according to the embodiment, by setting a limit on the dimensions of the wide head portions 21b and 22b, it is possible to prevent a decrease in vibration efficiency due to size reduction of the tuning-fork type piezoelectric vibrating piece 3.

In this way, the piezoelectric vibrating piece 3 according to the embodiment includes the base portion 20 and the pair of vibrating arm portions 21 and 22 extending in parallel from the base portion 20. The vibrating arm portions 21 and 22 include the arm portions 21a and 22a extending from the base portion 20 and head portions 21b and 22b connected to the distal ends of the arm portions 21a and 22a and having widths larger than those of the arm portion 21a and 22a. The piezoelectric vibrating piece 3 satisfies the following relation: 0.13×10¹²≤Vh(Lh²+Wh²)≤0.39×10¹², where Lh [μm] is a length of each of the head portions 21b and 22b, Wh [μm] is a width of each of the head portions 21b and 22b, and Vh [μm³] is a volume of each of the head portion 21b and 22b. According to this configuration, by numerically limiting dimension-based portions of the inertia moments during vibration of the head portions 21b and 22b, it is possible to prevent a change in frequency while reducing a CI value.

In addition, it is preferable that the piezoelectric vibrating piece 3 according to the embodiment satisfies the following relation: Vh(Lh²+Wh²)≤0.33×10¹². According to this configuration, the CI value can be reduced by about 5% compared to that when Vh(Lh²+Wh²)=0.39×10¹².

In addition, it is preferable that the piezoelectric vibrating piece 3 according to the embodiment further satisfies the following relation: 0.145×10¹²≤Vh (Lh²+Wh²). According to this configuration, the change in frequency can be reduced to within 5% from that when Vh(Lh²+Wh²)=0.13×10¹².

In addition, it is preferable that the piezoelectric vibrating piece 3 according to the embodiment satisfies the following relation: 0.24≤Lh/La≤0.35, where La [μm] is a length of each of the vibrating arm portions 21 and 22 from the base portion 20 to respective distal ends. According to this configuration, by numerically limiting a ratio of the length of each of the head portions 21b and 22b to the length of each of the vibrating arm portions 21 and 22, it is possible to reduce the change in frequency while reducing the CI value.

In addition, it is preferable that the piezoelectric vibrating piece 3 according to the embodiment further satisfies the following relation: Lh/La≤0.32. According to this configuration, the CI value can be reduced by about 5% compared to that when Lh/La=0.35.

In addition, it is preferable that the piezoelectric vibrating piece 3 according to the embodiment further satisfies the following relation: 0.27≤Lh/La. According to this configuration, the change in frequency can be reduced to within 5% from that when Lh/La=0.24.

In addition, the piezoelectric vibrating piece 3 according to the embodiment further includes the pair of side arms 23 and 24 extending from the base portion 20 and disposed on both sides of the pair of vibrating arm portions 21 and 22 in a width direction. According to this configuration, it is possible to prevent a decrease in vibration efficiency due to size reduction of the piezoelectric vibrating piece 3 including the pair of side arms 23 and 24.

In addition, the piezoelectric vibrator 1 according to the embodiment includes the piezoelectric vibrating piece 3, and the package 2 in which the piezoelectric vibrating piece 3 is sealed. According to this configuration, a small and high-quality piezoelectric vibrator 1 can be obtained.

In addition, the oscillator 100 according to the embodiment includes: the piezoelectric vibrator 1; and the integrated circuit 101 electrically connected to the piezoelectric vibrator 1. According to this configuration, a small and high-quality oscillator 100 can be obtained.

### Second Embodiment

Next, a second embodiment of the present disclosure will be described. In the following description, the same or equivalent configurations as those in the above-described embodiment are given the same reference numerals, and the description thereof will be simplified or omitted.

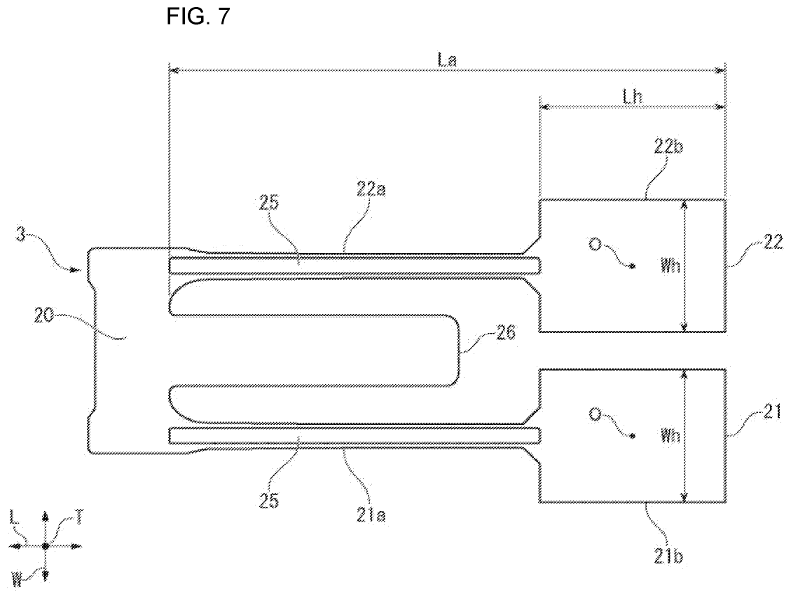

FIG. 7 is a plan view of the piezoelectric vibrating piece 3 according to the second embodiment.

As shown in FIG. 7, the piezoelectric vibrating piece 3 according to the second embodiment differs from the above-mentioned embodiment in that the piezoelectric vibrating piece 3 according to the second embodiment includes a center arm 26 extending from the base portion 20 and disposed between the pair of vibrating arm portions 21 and 22.

The center arm 26 has a substantially rectangular shape in a plan view, and is disposed between the pair of vibrating arm portions 21 and 22 in the width direction W. The center arm 26 extends parallel to the pair of vibrating arm portions 21 and 22 along the length direction L, and extends to the front of the head portions 21b and 22b.

In this case, the piezoelectric vibrating piece 3 is mounted such that a mount electrode (not shown) formed on the center arm 26 is brought into contact with an electrode pad of the package 2. Dimensional limitations of the wide head portions 21b and 22b, and the like are the same as in the first embodiment.

In this way, the piezoelectric vibrating piece 3 according to the second embodiment includes the center arm 26 extending from the base portion 20 and disposed between the pair of vibrating arm portions 21 and 22. According to this configuration, similarly to the first embodiment, it is possible to prevent a decrease in vibration efficiency due to size reduction of the piezoelectric vibrating piece 3 including the center arm 26.

It should be understood that although the preferred embodiments of the present disclosure have been described and illustrated, these disclosures are illustrative in the invention and should not be considered as limiting. Additions, omissions, substitutions, and other changes may be made without departing from the scope of the invention. Accordingly, the invention should not be considered limited by the foregoing descriptions, but rather by the scope of claims.

For example, in the above-mentioned embodiments, the piezoelectric vibrating piece 3 is exemplified as including the pair of side arms 23 and 24 or the center arm 26, but the piezoelectric vibrating piece 3 may not include the pair of side arms 23 and 24 or the center arm 26. In this case, the piezoelectric vibrating piece 3 may be mounted inside the package 2 using the base portion 20 as a mount portion.

What is claimed is:

1. A piezoelectric vibrating piece comprising:
a base portion; and
a pair of vibrating arm portions extending in parallel from the base portion, wherein
each of the vibrating arm portions includes:
an arm portion extending from the base portion; and
a head portion connected to a distal end of the arm portion and having a width larger than that of the arm portion, and
the piezoelectric vibrating piece satisfies the following relation:
$$0.13 \times 1012 \leq Vh ( Lh 2 + Wh 2 ) \leq 0.39 \times 1012$$
where Lh [μm] is a length of the head portion, Wh [μm] is a width of the head portion, and Vh [μm3] is a volume of the head portion.

2. The piezoelectric vibrating piece according to claim 1, wherein
the following relation is satisfied,
$$Vh ( Lh 2 + Wh 2 ) \leq 0.33 \times 1012.$$

3. The piezoelectric vibrating piece according to claim 1, wherein
the following relation is satisfied,
$$0.145 \times 1012 \leq Vh ( Lh 2 + Wh 2 ) .$$

4. The piezoelectric vibrating piece according to claim 2, wherein
the following relation is satisfied,
$$0.145 \times 1012 \leq Vh ( Lh 2 + Wh 2 ) .$$

5. The piezoelectric vibrating piece according to claim 1, wherein
the following relation is satisfied,
$$0.24 \leq Lh / La \leq 0.35$$
where La [μm] is a length of the vibrating arm portion from the base portion to the distal end.

6. The piezoelectric vibrating piece according to claim 2, wherein
the following relation is satisfied,
$$0.24 \leq Lh / La \leq 0.35$$
where La [μm] is a length of the vibrating arm portion from the base portion to the distal end.

7. The piezoelectric vibrating piece according to claim 5, wherein
the following relation is satisfied,
$$Lh / La \leq 0.32 .$$

8. The piezoelectric vibrating piece according to claim 6, wherein
the following relation is satisfied,
$$Lh / La \leq 0.32 .$$

9. The piezoelectric vibrating piece according to claim 5, wherein
the following relation is satisfied,
$$0.27 \leq Lh / La .$$

10. The piezoelectric vibrating piece according to claim 6, wherein
the following relation is satisfied,
$$0.27 \leq Lh / La .$$

11. The piezoelectric vibrating piece according to claim 1, further comprising:
a pair of side arms extending from the base portion and disposed on both sides of the pair of vibrating arm portions in a width direction.

12. The piezoelectric vibrating piece according to claim 2, further comprising:
a pair of side arms extending from the base portion and disposed on both sides of the pair of vibrating arm portions in a width direction.

13. The piezoelectric vibrating piece according to claim 1, further comprising:
a center arm extending from the base portion and disposed between the pair of vibrating arm portions.

14. The piezoelectric vibrating piece according to claim 2, further comprising:
a center arm extending from the base portion and disposed between the pair of vibrating arm portions.

15. A piezoelectric vibrator comprising:
the piezoelectric vibrating piece according to claim 1; and
a package in which the piezoelectric vibrating piece is sealed.

16. A piezoelectric vibrator comprising:
the piezoelectric vibrating piece according to claim 2; and
a package in which the piezoelectric vibrating piece is sealed.

17. An oscillator comprising:
the piezoelectric vibrator according to claim 15; and
an integrated circuit electrically connected to the piezoelectric vibrator.

18. An oscillator comprising:
the piezoelectric vibrator according to claim 16; and
an integrated circuit electrically connected to the piezoelectric vibrator.
